(19) United States
(12) Patent Application Publication
(10) Pub. No.: US 2002/0185743 A1
(43) Pub. Date: Dec. 12, 2002

(54) Wafer level chip-scale package and a method for manufacturing

(76) Inventor: Hyung Gil Baik, Kyoungki-do (KR)

Correspondence Address: Pillsbury Winthrop LLP, Intellectual Property Group, 1600 Tysons Boulevard, McLean, VA, 22101, US

(21) Appl. No.: 10/024,371

(22) Filed: Dec. 21, 2001

(30) Foreign Application Priority Data
Jun. 12, 2001 (KR) 2001-32874

(51) Int. Cl. H01L 23/48

(52) U.S. Cl. 257/777; 257/737; 257/773; 257/780

(57) ABSTRACT

The present invention relates to a wafer level chip-scale package and a method for manufacturing such a package. The chip-scale package includes a semiconductor chip having chip pads, a conductor formed on the semiconductor chip and connected to a corresponding chip pad ball land on an extended portion of the conductor, an adhesive layer provided between the semiconductor chip and the conductor, a conductive plug filling the opening part connecting the chip pad to the conductor, a molded body covering the conductor and conductive plug while exposing the ball lands, and a substrate onto which the inserted semiconductor chip is mounted conductive structures and provided to electrically connect and affix the semiconductor chip to the substrate.

### BACKGROUND OF THE INVENTION

1. Field of the Invention

The present invention relates to a package and a method of manufacturing the package and, more particularly, to a wafer level chip-scale package and a method of manufacturing a chip-scale package while the chips remain on a wafer.

2. Description of the Related Art

As widely known, traditionally each of the individual chips fabricated on a single semiconductor wafer is separated from the wafer by sawing or scribing. Each of the chips was then mounted on a lead frame and encasing in a molding composition to produce a packaged product (hereinafter “package”) that protected the chip from environmental moisture and impurities and provided external leads that could be electrically connected to external circuit boards.

A chip-scaled package, i.e., one that is molded to the size roughly equivalent to the space occupied by the chip itself, is a micro device that is a valuable commodity and which is very useful for increasing the mounting density on a circuit board as well as the integration density of various integrated circuits such as ASIC (application specific integrated circuit) devices.

FIG. 1 illustrates a cross-sectional view of a wafer level chip-scale package constructed according to a conventional method.

Referring to FIG. 1, a wafer level chip-scale package according to a conventional method comprises a semiconductor chip 100 having a plurality of chip pads 102 in the wafer state, metal lines 108 connected to the chip pad 102 and having a ball land (not shown in the drawing) at an extended portion thereof, a UBM formed on a portion of the metal line, an insulator protecting the resulting structure from the external environment, and a conductive ball mounted on the ball land.

A conventional prior art method of manufacturing a wafer level chip-scale package is described below with reference to FIG. 1. As shown in FIG. 1, a silicon oxide layer is formed on the semiconductor chip 100 by CVD (chemical vapor deposition). A first insulating layer 106 is then formed by patterning and etching the silicon oxide layer to expose the chip pad 102. A passivation layer 104 is formed between the chip pads 102.

A metal such as Ti, V or the like is then deposited on the first insulating layer 106 by sputtering. A first conductor 108 in contact with chip pad 102 is then formed by patterning and etching the metal layer.

A second insulating layer 110 is then formed on the first insulating layer 106 and the first conductor 108 so as to expose a extended portion of the first conductor 108.

Another metal such as Ti, V or the like is deposited on the second insulating layer 110 by sputtering. A second conductor 112 is then formed by etching the metal so that the remaining metal covers the exposed portion of the first conductor 108. In this case, the second conductor 112 is electrically connected to the chip pad 102 through the first conductor 108 and provides a ball land area on which a conductive ball will subsequently be formed.

A conductive ball 120 is then formed on the ball land area of the second conductor 112. The package is then completed by mounting the conductive ball 120 onto a substrate 140.

Unfortunately, when the conductive ball is mounted on the substrate according to conventional methods, cracks tend to be generated at the interface between the wafer and the substrate in contact with the conductive ball due in large part to the difference in the thermal expansion coefficients of the substrate and the chip, i.e., approximately 18 ppm for the substrate and 3-4 ppm for the semiconductor chip.

Moreover, the conventional methods require at least two metal sputtering processes for forming the first and second conductors, thereby complicating the package manufacturing process.

### SUMMARY OF THE INVENTION

Accordingly, the present invention is directed to a wafer level chip-scale package and method for manufacturing such packages that substantially overcomes one or more of the limitations and disadvantages of the prior art processes.

The object of the present invention is to provide a wafer level chip-scale package and a method for manufacturing such packages that simplifies package manufacturing by reducing the number of metal sputtering steps associated with forming the conductors. Another object of the present invention is to provide a wafer level chip-scale package and a method for manufacturing such packages that improves the reliance of the resulting devices by preventing or suppressing crack generation.

Additional features and advantages of the invention will be set forth in the description which follows, and in part will be apparent from the description, or may be learned and appreciated by practicing the invention. The objectives and other advantages of the invention will be realized by the structure detailed in the written description, illustrated in the figures, and defined by the claims.

To achieve these and other advantages, and in accordance with the purpose of the present invention as embodied and broadly described, a wafer level chip-scale package according to a first aspect of the present invention includes a semiconductor chip having a plurality of chip pads thereon, a conductor formed on the semiconductor chip so as to have an opening part exposing each of the chip pads and a ball land on an extending portion of the conductor, an adhesive layer inserted between the semiconductor chip and the conductor, a conductive layer covering the opening part so as to connect the chip pad to the conductor, a molding body covering the conductor and conductive layer but exposing the ball land, a conductive ball landed at the ball land, and a substrate on which the conductive ball is mounted.

In another aspect of the present invention, a wafer level chip-scale package includes a semiconductor chip having a plurality of chip pads thereon, a conductor formed on the semiconductor chip so as to have an opening part exposing each of the chip pads and a ball land on an extending portion of the conductor, an adhesive layer inserted between the semiconductor chip and the conductor, a conductive layer covering the opening part so as to connect the chip pad to the conductor, a molding body covering the conductor and conductive layer but exposing the ball land, a substrate on which the ball land is mounted, and a solder paste inserted between the ball land and the substrate.

In a third aspect of the present invention, a method of manufacturing a wafer level chip-scale package includes the steps of providing a semiconductor chip as a wafer state having a plurality of chip pads thereon, forming a conductor having an opening part exposing each of the chip pads, forming a ball land by half-etching the conductor, forming a conductive layer covering the opening part so as to connect the chip pads to the conductor, forming a molding body covering the resultant but exposing the ball land, landing a conductive ball on the ball land, and landing a conductive ball on the ball land.

In a fourth aspect of the present invention, a method of manufacturing a wafer level chip-scale package includes the steps of providing a semiconductor chip as a wafer state having a plurality of chip pads thereon, forming a conductor having an opening part exposing each of the chip pads, forming a ball land by half-etching the conductor, forming a conductive layer covering the opening part so as to connect the chip pad to the conductor, forming a molding body covering the resultant but exposing the ball land, and mounting the ball land on the substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 illustrates a cross-sectional view of a wafer level chip-scale package having a conventional construction;

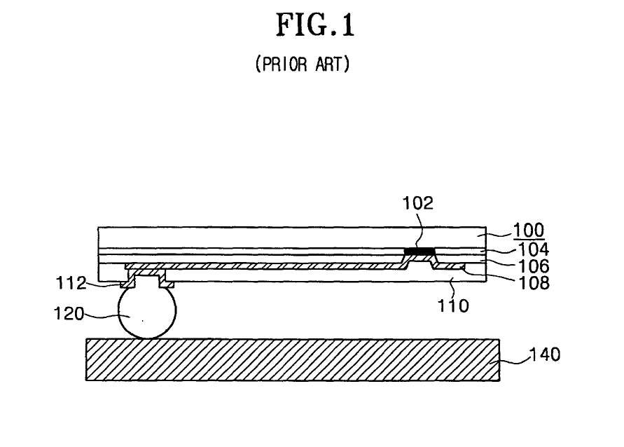

FIG. 2 illustrates a cross-sectional view of a wafer level chip-scale package according to an embodiment of the present invention;

FIGS. 3A. to 3G illustrate cross-sectional views of a manufacturing process for forming a wafer level chip-scale package according to an embodiment of the present invention;

FIG. 4 and FIG. 5 illustrate bird's-eye views of manufacturing a conductor according to an embodiment of the present invention;

FIG. 6 illustrates a cross-sectional view of a wafer level chip-scale package according to another embodiment of the present invention; and

FIG. 7 illustrates a cross-sectional view of a wafer level chip-scale package according to yet another embodiment of the present invention.

### DETAILED DESCRIPTION OF THE PREFERRED EMBODIMENTS

Reference will now be made in detail to the preferred embodiments of the present invention, examples of which are illustrated in the accompanying drawings. Where possible, the same reference numerals will be used to illustrate similar or corresponding elements throughout the specification.

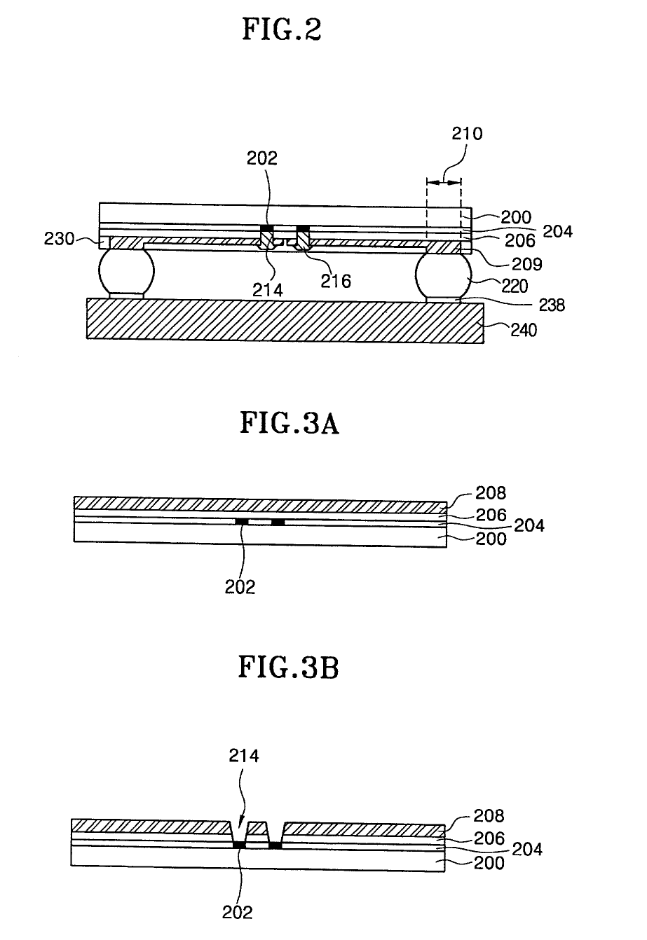

Referring to FIG. 2, a wafer level chip-scale package according to an embodiment of the present invention is constructed with a semiconductor chip 200 having a plurality of chip pads 202, an adhesive layer 206 formed on the semiconductor chip 200 with openings 214 exposing each of the chip pads 202, a conductor 209 formed on the adhesive layer 206 with a ball land 210 on a peripheral portion of the conductor 209, a conductive plug 216 filling the opening 214 to connect the chip pad 202 to the conductor 209, a molding layer 230 covering the resulting structure with the exception of the ball lands 210 which remain exposed, and conductive balls 220 attached to the ball lands 210.

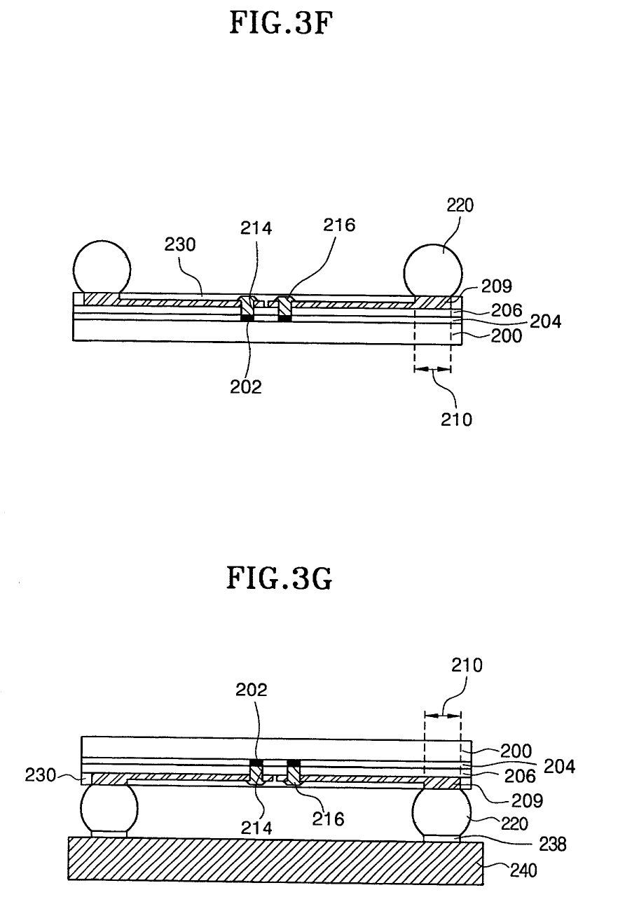

In this case, the conductor 209, as shown in FIG. 4 and FIG. 5, includes a ring portion 203 surrounding the opening 214, a ball land 210 formed on a extended portion of the conductor 214, and a trace 212 electrically connecting the ring portion 203 and the ball land 210.

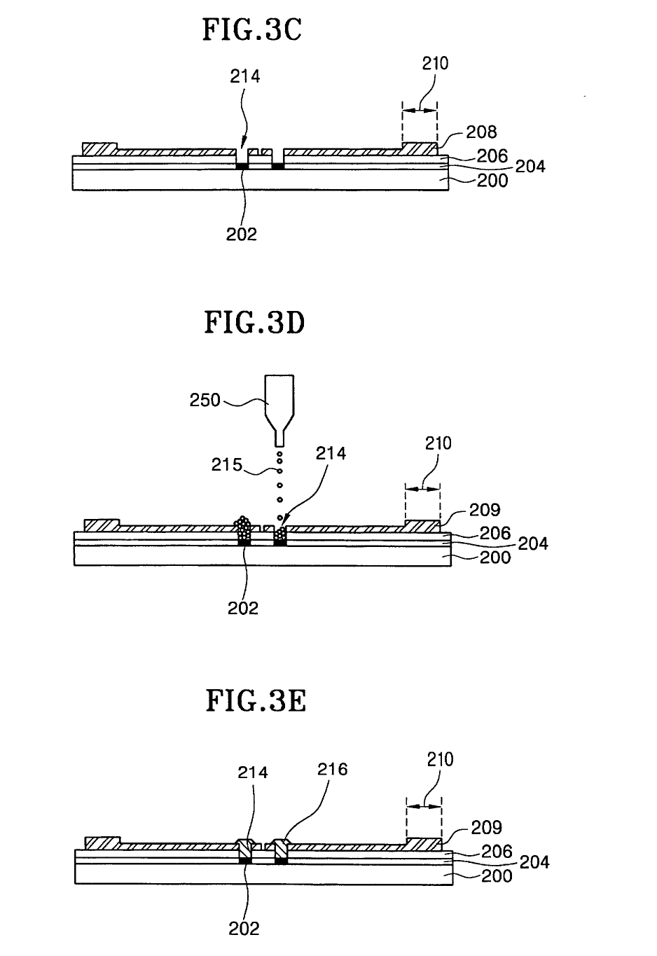

FIGS. 3A to FIGS. 3G illustrate cross-sectional views of steps in a process for manufacturing a wafer level chip-scale package according to a first embodiment of the present invention.

Referring to FIG. 3A, an insulating adhesive layer 206 that is patterned to expose chip pads 202 is preferably attached to a semiconductor chip 200 while in its wafer state by low temperature thermal pressing. In this case, the adhesive layer 206 is formed using a suitable polyimide based resin.

Moreover, an insulating layer 204 is formed on the semiconductor chip 200 while in its wafer state so as to cover the wafer surface between the exposed chip pads 202. A metal layer 208, preferably Cu, is then formed on the adhesive layer 206.

Referring to FIG. 3B and FIG. 4, an opening 214 is formed by selectively etching the metal layer 208 and the adhesive layer 206 to expose the chip pads 202.

Because the adhesive layer 206 is formed by low temperature thermal pressing, the metal layer used to form the conductor is not subjected to mechanical stresses resulting from thermal contraction and expansion.

Referring to FIG. 3C, a conductor 209 is formed by half-etching the metal layer selectively.

As shown in FIG. 5, a ball land 210 at which a conductive ball will be positioned, a ring 203 surrounding the chip pad 202, and a trace 212 connecting the ring 203 to the ball land 210 are patterned and etched from metal layer 208.

Referring to FIG. 3D, a solder plug 214 is formed by filling opening 214 with solder particles 215 from a solder injector 250.

Referring to FIG. 3E, conductive plug 216 connecting the chip pad 202 to conductor 209 is formed by reflowing the solder layer.

Referring to FIG. 3F, a fluid sealing material is then spin-coated onto the resulting structure including the conductor 209 and conductive plug 216. A molded body 230 is then formed by patterning and etching the sealing material to expose the ball lands 210. In this case, the portions of the molded body 230 are generally planar between adjacent ball lands 210 but could conform to more complex wafer topography.

Referring to FIG. 3G, conductive balls 220, such as solder balls, are landed on the ball lands 210. The chip 200 is then inverted positioned with respect to a substrate 240. Conductive balls 220 are then mounted onto substrate 240 to complete the package manufacturing process.

As illustrated in FIG. 3E, a solder paste may be provided between the conductive balls 220 and the substrate 240 to reinforce the adhesiveness and/or control the thickness of the resulting package.

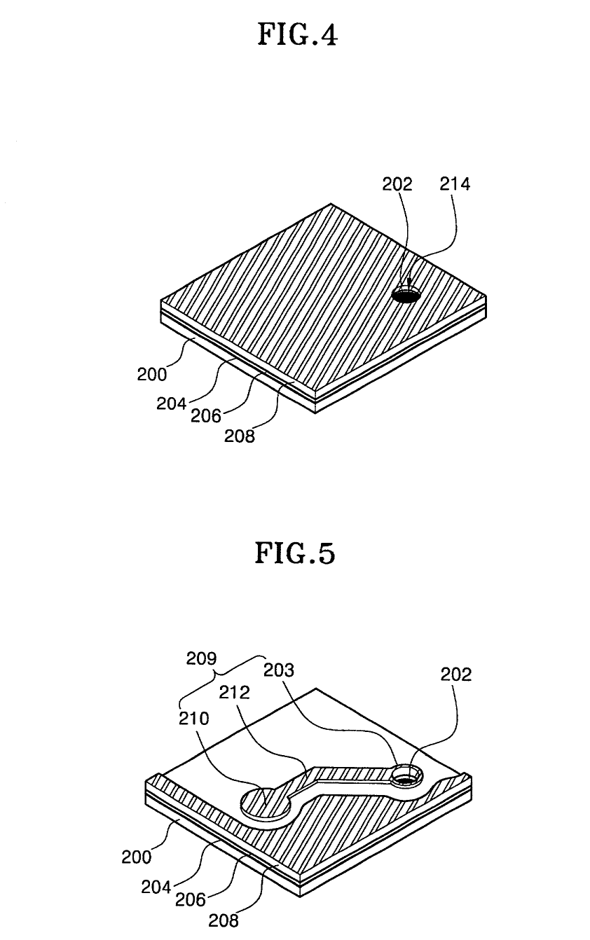

FIG. 6 illustrates a cross-sectional view of a wafer level chip-scale package according to a second embodiment of the present invention.

Referring to FIG. 6, the second embodiment of a wafer level chip-scale package according to the present invention includes a semiconductor chip 300 having a plurality of chip pads 302 with an insulating layer 304 covering the remainder of the chip surface, an adhesive layer 306 formed on the semiconductor chip 300 that exposes each of the chip pads 302 through openings 314, a conductor 309 formed on the adhesive layer 306 having ball lands 310 on extended portions, a conductive plug 316 filling the opening 314 to connect the chip pad 302 to conductor 309, a molding body 330 covering the resulting structure, with the exception of the ball lands 210, in which a least a portion of the molding body 330 having a convex surface extending between the ball lands, conductive balls 320 fixed to the ball lands 310, and a plating layer 338 provided between a substrate 340 and the conductive balls 320.

The method of manufacturing the wafer level chip-scale package according to the second embodiment of the present invention corresponds generally to the manufacturing method described above with regard to the first embodiment of the present invention. The manufacturing method, however, differs in that the spin-coated molded body 330 for the second embodiment is modified to provide a convex shape between the ball lands 310 by etch. The second embodiment also differs in that a plating layer 338 is formed between the substrate 340 and conductive ball 320.

The molding body 330 is formed by a combination of spin coating followed by a dotting process to increase the coating thickness selectively and thereby render the surface of the molding body 330 convex in the space between the ball lands 310.

In a third embodiment of the present invention, a solder paste is inserted between the substrate and conductive ball 320 so as to reinforce the adhesiveness as well as control the thickness of the package.

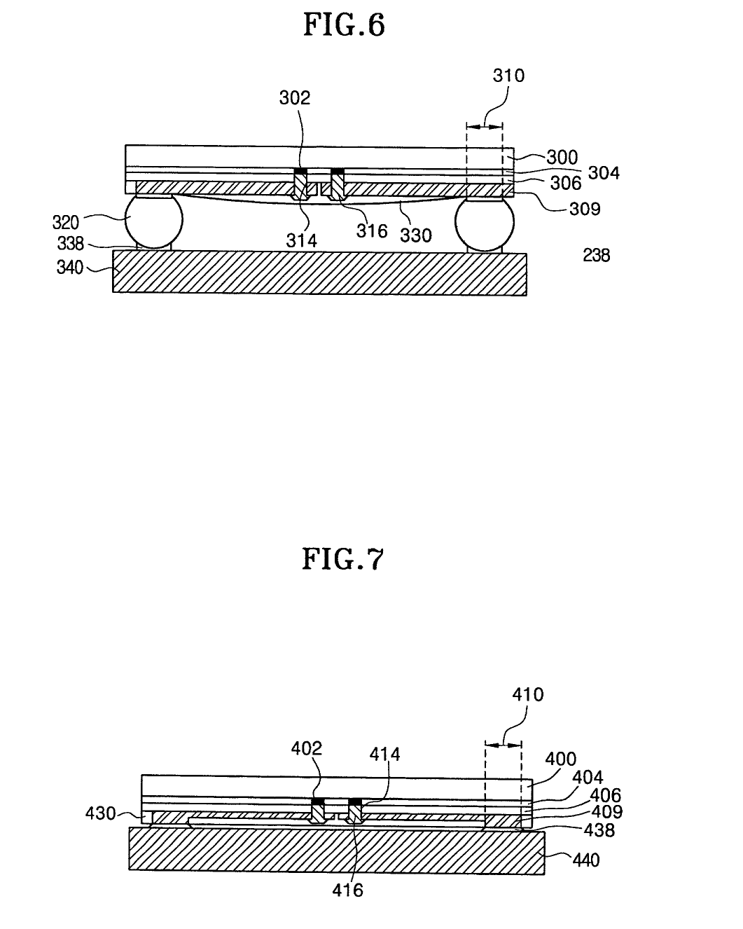

FIG. 7 illustrates a cross-sectional view of a wafer level chip-scale package according to a fourth embodiment of the present invention.

Referring to FIG. 7, the fourth embodiment of a wafer level chip-scale package according to the present invention is constructed with a semiconductor chip 400 having a plurality of chip pads 402, an adhesive layer 406 formed on the semiconductor chip 400 with openings 414 that expose each of the chip pads 402, conductors 409 formed on the adhesive layer 406 having ball lands 410 on extended portions of the conductors 409, a conductive layer 416 filling the openings 414 and connecting the chip pads 402 to the conductors 409, a molded 430 body covering the resulting structure, with the exception the ball lands 410, a substrate 440 onto which the ball lands 410 are landed, and solder paste areas 438 inserted between the ball lands 410 and the substrate 440.

The method of manufacturing the wafer level chip-scale package according to the fourth embodiment of the present invention is similar to that used to manufacture the first, second, and third embodiments of the present invention. This method, however, differs in that the ball lands 410 are directly mounted on the substrate 440 without using an intermediate conductive ball. A further difference is that the solder paste 438 is provided between the ball land 410 and substrate 440. Another difference is that the ball lands 410 are preferably formed by a plating process.

Accordingly, the present invention provides improved control of the thickness of the conductor by forming the adhesive layer and the metal layer on the substrate thereby, simplifing the package manufacturing process without requiring additional sputtering steps, and improving the reliability of the solder joint by providing a thicker adhesive layer.

Moreover, the present invention forms the adhesive layer using a low temperature pressing process, thereby preventing the thermal contraction of the metal layer.

Further, the present invention provides solder paste between the substrate and conductive ball and thickens the metal layer sufficiently, thereby preventing crack generation and propagation.

Finally, the present invention forms the conductive plug connecting the chip pad and the conductor by solder jetting, thereby securing stable electric characteristics.

The foregoing embodiments are merely exemplary and should not to be construed as unnecessarily limiting the present invention. It is contemplated that those of ordinary skill can readily apply the present teachings to other types of devices and situations. The description of the present invention is intended to be illustrative, and not to limit the scope of the claims. Many alternatives, modifications, and variations will be apparent to those skilled in the art.

What is claimed is:

1. A wafer level chip-scale package comprising:
a semiconductor chip, the semiconductor chip comprising a plurality of chip pads on a surface of the semiconductor chip;
an insulating layer formed on the surface of the semiconductor chip; the insulating layer comprising openings that expose the chip pads;
a conductor formed on a portion of the insulating layer, the conductor having a contact portion adjacent the opening, a ball land portion positioned remotely from the contact portion, and a trace portion providing electrical connection between the contact portion and the ball land portion;
a conductive plug filling the openings and providing electrical connection between the chip pad and the contact portion of the conductor;
a molding body covering the insulating layer, the conductive plug, and the contact portion and the trace portion of the conductor, the ball land portion remaining exposed;
a conductive ball landed on and in electrical contact with the ball land portion of the conductor; and
a substrate on which the conductive ball is mounted.

2. A wafer level chip-scale package according to claim 1, wherein the insulating layer further comprises an adhesive layer of a polyimide based resin.

3. A wafer level chip-scale package according to claim 1, wherein
the contact portion of the conductor comprises a ring on the insulating layer surrounding the opening part; and
the trace portion of the conductor comprises an elongated structure connecting the ring to the ball land portion.

4. A wafer level chip-scale package according to claim 1, wherein the conductive plug comprises solder.

5. A wafer level chip-scale package according to claim 1, wherein a plating region is provided on the substrate and positioned to contact the conductive ball as the semiconductor chip is mounted on the substrate.

6. A wafer level chip-scale package according to claim 1, wherein a solder paste is further inserted between the substrate and the conductive ball.

7. A wafer level chip-scale package according to claim 1, wherein a portion of the molding body between adjacent ball lands is substantially planar.

8. A wafer level chip-scale package according to claim 1, wherein a portion of the molding body between adjacent ball lands is convex.

9. A wafer level chip-scale package according to claim 1, wherein the conductive ball is a solder ball.

10. A wafer level chip-scale package comprising:
a semiconductor chip having a plurality of chip pads thereon;
an adhesive layer formed on the semiconductor chip, the adhesive layer having first openings exposing the chip pads;
a plurality of conductors formed on the adhesive layer, each conductor comprising a second opening portion adjacent to and exposing a chip pad, a ball land, and a trace providing electrical connection between the second opening portion and the ball land;
a plurality of conductive plugs filling the first openings and contacting the adjacent second opening portion of one conductor, each of the conductive plugs providing an electrical connection between one of the chip pads and the second opening portion of one of the conductors;
a molding body covering the conductors, adhesive layer, and conductive plugs but exposing the ball lands;
a substrate on which the ball lands are mounted; and
a solder paste provided between the ball lands and the substrate.

11. A wafer level chip-scale package according to claim 10, wherein the adhesive layer comprises a polyimide based resin.

12. A wafer level chip-scale package according to claim 10, each of the conductors comprising: a ring surrounding one of the first openings; and
a trace connecting the ring to one of the ball lands.

13. A wafer level chip-scale package according to claim 10, wherein the conductive plugs comprise solder.

14. A wafer level chip-scale package according to claim 10, wherein a portion of the molding body between adjacent ball lands is substantially planar.

15. A wafer level chip-scale package according to claim 10, wherein the conductive ball is a solder ball.

16. A wafer level chip-scale package according to claim 10, wherein the ball lands are plated.

17. A method of manufacturing a wafer level chip-scale package comprising the steps of:
providing a plurality of semiconductor chips on a single semiconductor wafer, each of the semiconductor chips comprising a plurality of chip pads;
forming an adhesive layer on each of the semiconductor chips, the adhesive layer including openings that expose a plurality of chip pads;
forming a plurality of conductors on each of the semiconductor chips, each of the conductors having an opening exposing a chip pad and an half-etched ball land;
forming a conductive plug, the conductive plug filling an opening and connecting a first chip pad to a first conductor;
forming a molding body on the semiconductor wafer that substantially covers the adhesive layer, the conductors, and the conductive plugs, but leaves a first ball land exposed;
landing a conductive ball on the first ball land by coating a solder paste thereon; and
mounting the conductive ball on a substrate.

18. A method of manufacturing a wafer level chip-scale package according to claim 17, wherein the step of forming the conductors further comprises:
forming a metal ring surrounding an opening; and forming a trace connecting the metal ring to a ball land.

19. A method of manufacturing a wafer level chip-scale package according to claim 17, wherein the step of forming the adhesive layer comprises attaching a polyimide based resin to the semiconductor chips.

20. A method of manufacturing a wafer level chip-scale package according to claim 17, wherein the ball land is formed by plating.

21. A method of manufacturing a wafer level chip-scale package according to claim 17, wherein the step of forming the conductive plug further comprises filling the opening with solder particles by jetting.

22. A method of manufacturing a wafer level chip-scale package according to claim 17, wherein the molding body is formed by spin coating.

23. A method of manufacturing a wafer level chip-scale package according to claim 17, wherein the step of forming the molding body further comprises:
spin-coating fluid molding composition onto the semiconductor chip and
dotting portions of the semiconductor chip between ball lands with additional fluid molding composition and thereby render a surface of the molding body convex between adjacent ball lands.

24. A method of manufacturing a wafer level chip-scale package comprising the steps of:
providing a plurality of semiconductor chips on a single semiconductor wafer, each of the semiconductor chips comprising a plurality of chip pads;
forming an adhesive layer on each of the semiconductor chips;
forming a plurality of conductors on the adhesive layer, each conductor having an opening exposing one chip pad and a ball land;
forming a ball land by half-etching the conductor;
forming a conductive plug filling the opening and connecting a first chip pad to a first conductor;
forming a molding body, the molding body covering most portions of the semiconductor chip but leaving the a first ball land exposed;
mounting the first ball land on a substrate by inserting a solder paste therebetween; and
mounting the ball land on the substrate.

25. A method of manufacturing a wafer level chip-scale package according to claim 24, wherein the adhesive layer comprises a polyimide based resin.

26. A method of manufacturing a wafer level chip-scale package according to claim 24, further comprising a step of plating the ball land.

27. A method of manufacturing a wafer level chip-scale package according to claim 24, wherein the conductive plug is formed by filling the opening with solder particles by jetting the solder particles into the opening.

28. A method of manufacturing a wafer level chip-scale package according to claim 24, wherein the step of forming the molding body comprises spin coating the semiconductor wafer with a molding material, the surface of the molded body between adjacent ball lands being substantially planar.
